(19) United States
(12) Patent Application Publication
(10) Pub. No.: US 2017/0294547 A1
(43) Pub. Date: Oct. 12, 2017

(54) SEMICONDUCTOR LAYERED STRUCTURE, PHOTODIODE AND SENSOR

(71) Applicant: SUMITOMO ELECTRIC INDUSTRIES, LTD., Osaka-shi, Osaka (JP)

(72) Inventors: Kaoru SHIBATA, Itami-shi (JP); Koji NISHIZUKA, Itami-shi (JP); Suguru ARIKATA, Itami-shi (JP); Takashi KYONO, Itami-shi (JP); Katsushi AKITA, Itami-shi (JP)

(73) Assignee: SUMITOMO ELECTRIC INDUSTRIES, LTD., Osaka-shi, Osaka (JP)

(21) Appl. No.: 15/507,854

(22) PCT Filed: Oct. 21, 2015
(86) PCT No.: PCT/JP2015/079707

§ 371 Date: Mar. 1, 2017

(30) Foreign Application Priority Data
Oct. 29, 2014 (JP) 2014-220757
Oct. 29, 2014 (JP) 2014-220758

(51) Int. Cl. H01L 31/0352; H01L 31/0304

(52) U.S. Cl. CPC H01L 31/035236; H01L 31/03046; H01L 31/0304

(57) ABSTRACT

A semiconductor layered structure includes a base layer, a quantum well structure, and a contact layer. The base layer, the quantum well structure, and the contact layer are disposed so as to be stacked in this order. In the contact layer, a region including a first main surface that is a main surface on a quantum well structure side has a p-type impurity concentration lower than a p-type impurity concentration of a region including a second main surface that is a main surface opposite to the first main surface. A photodiode includes the semiconductor layered structure and an electrode formed on the semiconductor layered structure. A sensor includes the photodiode and a read-out circuit connected to the photodiode.

### TECHNICAL FIELD

The present invention relates to a semiconductor layered structure, a photodiode, and a sensor.

This application claims priorities based on Japanese Patent Application No. 2014-220757 filed on Oct. 29, 2014 and Japanese Patent Application No. 2014-220758 filed on Oct. 29, 2014, and the entire contents of these Japanese Patent Applications are herein incorporated by reference.

### BACKGROUND ART

A semiconductor layered structure including a structure in which a semiconductor layer formed of a III-V compound semiconductor is formed on a substrate formed of a III-V compound semiconductor can be used for, for example, producing a photodiode designed for light in the near-infrared region. Specifically, for example, an infrared photodiode can be obtained by sequentially stacking, on a substrate formed of a III-V compound semiconductor, a buffer layer, an absorption layer, and a contact layer that are formed of III-V compound semiconductors, and further forming appropriate electrodes. Of such photodiodes, a photodiode that has a cutoff wavelength of 2 μm or more has been reported (for example, refer to Non Patent Literature 1).

### CITATION LIST

### Patent Literature

NPL 1: R. Sidhu, et al., “A Long-Wavelength Photodiode on InP Using Lattice-Matched GaInAs—GaAsSb Type-II Quantum Wells”, IEEE PHOTONICS TECHNOLOGY LETTERS, VOL. 17, NO. 12, DECEMBER 2005, p. 2715-2717

### SUMMARY OF INVENTION

### Technical Problem

There has been a demand for a further increase in the sensitivity of the above-described photodiode. Accordingly, an object is to provide a semiconductor layered structure, a photodiode, and a sensor that enable an increase in the sensitivity.

### Solution to Problem

A semiconductor layered structure according to the present invention includes a base layer formed of a III-V compound semiconductor and having an n-type conductivity; a quantum well structure formed of a III-V compound semiconductor; and a contact layer formed of a III-V compound semiconductor and having a p-type conductivity. The base layer, the quantum well structure, and the contact layer are disposed so as to be stacked in this order. In the contact layer, a region including a first main surface that is a main surface on a quantum well structure side has a p-type impurity concentration lower than a p-type impurity concentration of a region including a second main surface that is a main surface opposite to the first main surface.

A photodiode according to the present invention includes the semiconductor layered structure and an electrode formed on the semiconductor layered structure.

A sensor according to the present invention includes the photodiode and a read-out circuit connected to the photodiode.

### Advantageous Effects of Invention

The above-described semiconductor layered structure, photodiode, and sensor enable the achievement of an increase in the sensitivity.

### BRIEF DESCRIPTION OF DRAWINGS

FIG. 1 is a schematic sectional view illustrating the structure of a semiconductor layered structure according to Embodiment 1.

FIG. 2 is a schematic sectional view illustrating the structure of a photodiode according to Embodiment 1.

FIG. 3 is a flowchart schematically illustrating a method for producing a semiconductor layered structure and a photodiode according to Embodiment 1.

FIG. 4 is a schematic sectional view illustrating a method for producing a semiconductor layered structure and a photodiode according to Embodiment 1.

FIG. 5 is a schematic sectional view illustrating a method for producing a semiconductor layered structure and a photodiode according to Embodiment 1.

FIG. 6 is a schematic sectional view illustrating a method for producing a semiconductor layered structure and a photodiode according to Embodiment 1.

FIG. 7 is a schematic sectional view illustrating a method for producing a semiconductor layered structure and a photodiode according to Embodiment 1.

FIG. 8 is a schematic sectional view illustrating the structure of a semiconductor layered structure according to Embodiment 2.

FIG. 9 is a schematic sectional view illustrating the structure of a photodiode according to Embodiment 2.

FIG. 10 is a schematic sectional view illustrating the structure of a semiconductor layered structure according to Embodiment 3.

FIG. 11 is a schematic sectional view illustrating the structure of a photodiode according to Embodiment 3.

FIG. 12 is a schematic sectional view illustrating the structure of a photodiode and a sensor according to Embodiment 4.

### DESCRIPTION OF EMBODIMENTS

### [Description of Embodiments of Invention of the Present Application]

Embodiments according to the invention of the present application will be first listed and described. A semiconductor layered structure according to the present application includes a base layer formed of a III-V compound semiconductor and having an n-type conductivity; a quantum well structure formed of a III-V compound semiconductor; and a contact layer formed of a III-V compound semiconductor and having a p-type conductivity. The base layer, the quantum well structure, and the contact layer are disposed so as to be stacked in this order. In the contact layer, a region including a first main surface that is a main surface on a quantum well structure side has a p-type impurity concentration lower than a p-type impurity concentration of a region including a second main surface that is a main surface opposite to the first main surface.

The inventors of the present invention performed studies on how to increase the sensitivity of a photodiode including a structure in which a base layer, a quantum well structure, and a contact layer that are formed of III-V compound semiconductors are stacked. As a result, they have found that a p-type impurity introduced into the contact layer having a p-type conductivity for the purpose of generating the majority carriers in the contact layer, diffuses into the quantum well structure functioning as an absorption layer, which results in a decrease in the sensitivity.

In the semiconductor layered structure according to the present application, in the contact layer, a region including a first main surface that is a main surface on a quantum well structure side has a p-type impurity concentration set to be lower than the p-type impurity concentration of a region including a second main surface that is a main surface opposite to the first main surface. The region including the first main surface, which is a main surface on the quantum well structure side, has a p-type impurity concentration set to be lower, to thereby suppress diffusion of the p-type impurity into the quantum well structure. Thus, the sensitivity can be increased. In addition, the region including the second main surface, which is a main surface opposite to the first main surface, has a p-type impurity concentration set to be higher, to thereby decrease the contact resistance between the contact layer and an electrode to be disposed in contact with the second main surface.

Thus, the semiconductor layered structure according to the present application enables an increase in the sensitivity of a photodiode produced from the semiconductor layered structure.

In the semiconductor layered structure, the contact layer includes a first contact layer disposed so as to include the first main surface, and a second contact layer disposed so as to include the second main surface. A p-type impurity concentration of the first contact layer is lower than a p-type impurity concentration of the second contact layer.

In this case, the semiconductor layered structure can be easily produced in which the region including the first main surface has a lower p-type impurity concentration than the region including the second main surface.

In the semiconductor layered structure, the first contact layer may have a p-type impurity concentration of less than 5×10¹⁸ cm⁻³. In this case, diffusion of the p-type impurity into the quantum well structure can be suppressed with more certainty.

In the semiconductor layered structure, the second contact layer may have a p-type impurity concentration of 8×10¹⁷ cm⁻³ or more. In this case, the contact resistance between the contact layer and an electrode to be disposed in contact with the second main surface can be easily decreased.

The semiconductor layered structure may further include a diffusion block layer formed of a III-V compound semiconductor, disposed between the quantum well structure and the contact layer, and having a p-type impurity concentration of 1×10¹⁶ cm⁻³ or less. The diffusion block layer having a low p-type impurity concentration is disposed between the contact layer and the quantum well structure, to thereby suppress diffusion of the p-type impurity into the quantum well structure with more certainty. As a result, a photodiode produced from the semiconductor layered structure can have an increased sensitivity.

In the semiconductor layered structure, the diffusion block layer may contain a p-type impurity that is at least one element selected from the group consisting of Zn, Be, Mg, and C. The diffusion block layer that has a lower content of such a p-type impurity preferably contained in the contact layer is employed, to thereby suppress diffusion of the p-type impurity into the quantum well structure. Thus, the sensitivity can be effectively increased.

In the semiconductor layered structure, the diffusion block layer may have a thickness of 100 nm or more and 2000 nm or less. The diffusion block layer is formed so as to have a thickness in such a range, to thereby suppress diffusion of the p-type impurity into the quantum well structure, and to achieve a high sensitivity with more certainty.

In the semiconductor layered structure, the quantum well structure may be a type-II structure including a repeating structure selected from the group consisting of InGaAs/GaAsSb, GaInNAs/GaAsSb, and InAs/GaSb. Such a type-II quantum well structure including a repeating structure is suitable as the absorption layer of a photodiode. Thus, the semiconductor layered structure that is particularly suitable for the production of a photodiode can be obtained.

A photodiode according to the present application includes the semiconductor layered structure and an electrode formed on the semiconductor layered structure. The photodiode according to the present application includes the semiconductor layered structure in which diffusion of the p-type impurity from the contact layer into the quantum well structure is suppressed, to thereby have a high sensitivity.

A sensor according to the present application includes the photodiode and a read-out circuit connected to the photodiode. The sensor according to the present application includes the photodiode according to the present application, to thereby have a high sensitivity.

### [Details of Embodiments of Invention of the Present Application]

### Embodiment 1

Hereinafter, Embodiment 1, which relates to a semiconductor layered structure according to an embodiment of the present invention, will be described with reference to drawings. Incidentally, like or corresponding elements in the drawings below are denoted by like reference numerals and redundant descriptions thereof will be omitted.

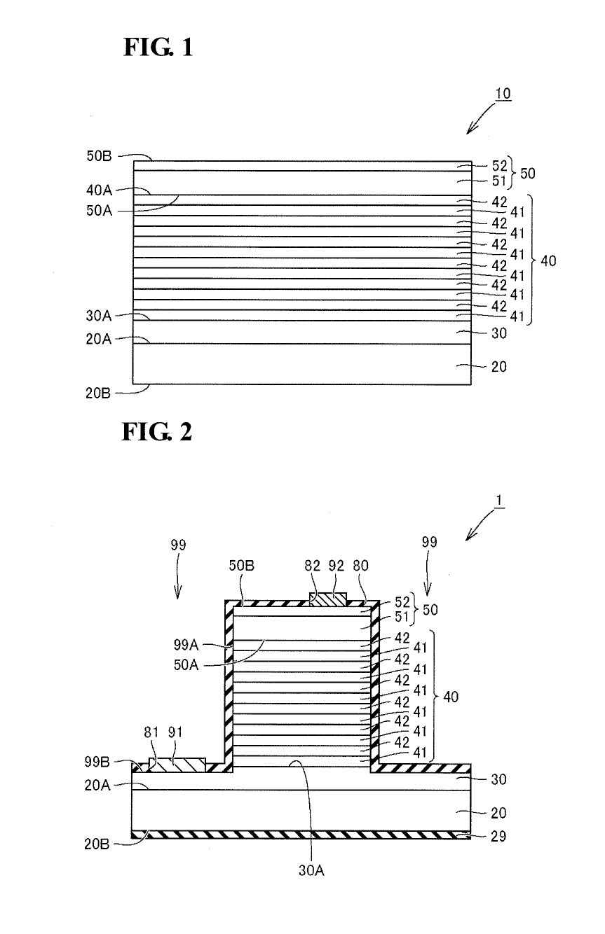

Referring to FIG. 1, a semiconductor layered structure 10 according to this embodiment includes a substrate 20, a buffer layer 30, a quantum well structure 40, and a contact layer 50. The substrate 20, the buffer layer 30, the quantum well structure 40, and the contact layer 50 are each formed of a III-V compound semiconductor. The substrate 20 and the buffer layer 30 constitute a base layer.

The substrate 20 is formed of a III-V compound semiconductor. The substrate 20 has a diameter of 50 mm or more, for example, 3 inches. Examples of the III-V compound semiconductor forming the substrate 20 include InP (indium phosphide), GaSb (gallium antimonide), InAs (indium arsenide), and GaAs (gallium arsenide). The substrate 20 formed of such a III-V compound semiconductor is employed to thereby obtain the semiconductor layered structure 10 suitable for production of a photodiode for infrared light. For the purpose of increasing the production efficiency and yield of semiconductor devices produced from the semiconductor layered structure 10, the substrate 20 may have a diameter of 80 mm or more (for example, 4 inches), or 105 mm or more (for example, 5 inches), or 130 mm or more (for example, 6 inches). An impurity that causes n-type carriers to be generated (n-type impurity) is introduced into the substrate 20. Examples of the n-type impurity contained in the substrate 20 include Si (silicon), Ge (germanium), S (sulfur), Sn (tin), and Te (tellurium). Thus, the substrate 20 has an n-type conductivity.

The buffer layer 30 is disposed so as to be on and in contact with a main surface 20A, which is one of the main surfaces of the substrate 20. Examples of the compound semiconductor forming the buffer layer 30 include InGaAs (indium gallium arsenide), InP, GaAs, GaP (gallium phosphide), GaSb, and InAs. The buffer layer 30 may be constituted by plural layers, for example, may have a configuration in which an InGaAs layer is formed on an InP layer. An n-type impurity is introduced into the buffer layer 30. Examples of the n-type impurity contained in the buffer layer 30 include Si, Ge, S, Sn, and Te. Thus, the buffer layer 30 has an n-type conductivity.

The quantum well structure 40 is formed on and in contact with a main surface 30A of the buffer layer 30, the main surface 30A being on a side of the buffer layer 30 opposite to the other side facing the substrate 20. The quantum well structure 40 has a structure in which two component layers foamed of III-V compound semiconductors are alternately stacked. More specifically, the quantum well structure 40 has a structure in which a first component layer 41 and a second component layer 42 are alternately stacked. A material for forming the first component layer 41 is, for example, GaAs Sb (gallium arsenide antimonide). A material for forming the second component layer 42 is, for example, InGaAs. The quantum well structure 40 preferably has a thickness of 500 nm or more. In this case, a photodiode produced from the semiconductor layered structure 10 can have an increased sensitivity.

The first component layer 41 and the second component layer 42 may each have a thickness of 3 nm, for example. The quantum well structure 40 may include, for example, a stack of 250 unit structures each constituted by the first component layer 41 and the second component layer 42. The quantum well structure 40 may be formed as a type-II multiple quantum well having such a structure.

The quantum well structure 40 that has a structure in which a GaAsSb layer and an InGaAs layer are alternately stacked is suitable as an absorption layer for near-infrared light. Thus, employment of such a structure makes the semiconductor layered structure 10 be suitable for producing a photodiode for near-infrared light. Incidentally, the combination of III-V compound semiconductors forming the first component layer 41 and the second component layer 42 is not limited to this combination, and examples thereof include a combination of GaInNAs and GaAsSb, and a combination of InAs and GaSb. The quantum well structure 40 is not limited to a multiple quantum well, and may be a single quantum well constituted by a single layer.

Referring to FIG. 1, the contact layer 50 is disposed on and in contact with a main surface 40A of the quantum well structure 40, the main surface 40A being on a side of the quantum well structure 40 opposite to the other side facing the buffer layer 30. Examples of the III-V compound semiconductor forming the contact layer 50 include InGaAs, InAs, GaSb, GaAs, and InP. An impurity that causes p-type carriers to be generated (p-type impurity) is introduced into the contact layer 50. Examples of the p-type impurity contained in the contact layer 50 include Zn (zinc), Be (beryllium), Mg (magnesium), and C (carbon). Thus, the contact layer 50 has a p-type conductivity.

The contact layer 50 includes a first contact layer 51 disposed so as to include a first main surface that is a main surface on the quantum well structure 40 side, and a second contact layer 52 disposed so as to include a second main surface 50B that is a main surface opposite to a first main surface 50A. The p-type impurity concentration of the first contact layer 51 is lower than the p-type impurity concentration of the second contact layer 52. Thus, the p-type impurity concentration of a region including the first main surface 50A, which is a main surface of the contact layer 50 on the quantum well structure 40 side, is lower than the p-type impurity concentration of a region including the second main surface 50B, which is a main surface opposite to the first main surface 50A.

In the semiconductor layered structure 10 according to this embodiment, in the contact layer 50, the p-type impurity concentration of a region including the first main surface 50A, which is a main surface on the quantum well structure 40 side, is set to be lower than the p-type impurity concentration of a region including the second main surface 50B, which is a main surface opposite to the first main surface 50A. The p-type impurity concentration of the region including the first main surface 50A, which is a main surface on the quantum well structure 40 side, is set to be lower, to thereby suppress diffusion of the p-type impurity into the quantum well structure 40 and contribute to an increase in the sensitivity. The p-type impurity concentration of the region including the second main surface 50B, which is a main surface opposite to the first main surface 50A, is set to be higher, to thereby decrease the contact resistance between the contact layer 50 and an electrode to be disposed in contact with the second main surface 50B. Thus, the semiconductor layered structure 10 according to this embodiment enables an increase in the sensitivity of the photodiode produced from the semiconductor layered structure 10.

In the semiconductor layered structure 10, the first contact layer 51 preferably has a p-type impurity concentration of less than 5×10¹⁸ cm⁻³. In this case, diffusion of the p-type impurity into the quantum well structure 40 can be suppressed with more certainty. From the viewpoint of further suppression of diffusion of the p-type impurity into the quantum well structure 40, the first contact layer 51 more preferably has a p-type impurity concentration of less than 1×10¹⁸ cm⁻³, still more preferably less than 5×10¹⁷ cm⁻³. The first contact layer 51 may have a thickness of 50 nm or more, preferably 400 nm or more. In this case, diffusion of the impurity can be suppressed with more certainty. However, when the first contact layer 51 has an excessively large thickness, the sensitivity is decreased. The first contact layer 51 preferably has a thickness of 2000 nm or less.

In the semiconductor layered structure 10, the second contact layer 52 preferably has a p-type impurity concentration of 8×10¹⁷ cm⁻³ or more. In this case, the contact resistance between the contact layer 50 and an electrode to be disposed in contact with the second main surface 50B can be easily decreased. From the viewpoint of further decreasing the contact resistance between the contact layer 50 and the electrode to be disposed in contact with the second main surface 50B, the second contact layer 52 more preferably has a p-type impurity concentration of 1×10¹⁸ cm⁻³ or more, still more preferably 5×10¹⁸ cm⁻³ or more.

Hereinafter, an infrared photodiode (photodiode) that is an example of the photodiode produced from the semiconductor layered structure 10 will be described. Referring to FIG. 2, an infrared photodiode 1 according to this embodiment is produced from the above-described semiconductor layered structure 10 according to this embodiment. As with the semiconductor layered structure 10, the infrared photodiode 1 includes the stack of the substrate 20, the buffer layer 30, the quantum well structure 40, and the contact layer 50. In the infrared photodiode 1, a trench 99 is forming that extends through the contact layer 50 and the quantum well structure 40 to reach the buffer layer 30. In other words, on a side wall 99A of the trench 99, the contact layer 50 and the quantum well structure 40 are exposed. A bottom wall 99B of the trench 99 is positioned within the buffer layer 30.

The infrared photodiode 1 further includes a passivation film 80, an n-electrode 91, a p-electrode 92, and an antireflection film 29. The passivation film 80 is disposed so as to cover the bottom wall 99B of the trench 99, the side wall 99A of the trench 99, and the second main surface 50B, which is a main surface of the contact layer 50 on a side opposite to the other side facing the quantum well structure 40. The passivation film 80 is formed of an insulator such as silicon nitride or silicon oxide.

The passivation film 80, which covers the bottom wall 99B of the trench 99, has an opening 81 formed so as to extend through the passivation film 80 in the thickness direction. The n-electrode 91 is disposed so as to fill the opening 81. The n-electrode 91 is disposed so as to be in contact with the buffer layer 30 exposed through the opening 81. The n-electrode 91 is formed of an electric conductor such as metal. More specifically, the n-electrode 91 may be constituted by Ti (titanium)/Pt (platinum)/Au (gold), for example. The n-electrode 91 forms an ohmic contact with the buffer layer 30.

The passivation film 80, which covers the second main surface 50B of the contact layer 50, has an opening 82 formed so as to extend through the passivation film 80 in the thickness direction. The p-electrode 92 is disposed so as to fill the opening 82. The p-electrode 92 is disposed so as to be in contact with the contact layer 50 exposed through the opening 82. The p-electrode 92 is formed of an electric conductor such as metal. More specifically, the p-electrode 92 may be constituted by Ti/Pt/Au, for example. The p-electrode 92 forms an ohmic contact with the contact layer 50.

The antireflection film 29 is formed so as to cover the other main surface 20B of the substrate 20. The antireflection film 29 is formed of SiON (silicon oxynitride), for example. The antireflection film 29 is formed, to thereby suppress reflection of light incoming through the other main surface 20B of the substrate 20. Thus, the sensitivity of the infrared photodiode 1 is increased.

When infrared rays pass through the other main surface 20B of the substrate 20 into the infrared photodiode 1, the infrared rays are absorbed between quantum levels within the quantum well structure 40, resulting in generation of electron-hole pairs. The generated electrons and holes are output as photocurrent signals from the infrared photodiode 1. Thus, the infrared rays are detected.

Incidentally, the p-electrode 92 is a pixel electrode. The infrared photodiode 1 may include only one p-electrode 92 that is a pixel electrode as illustrated in FIG. 2, or may include plural pixel electrodes (p-electrodes 92). Specifically, the infrared photodiode 1 may have a structure in which plural unit structures each illustrated in FIG. 2 are arranged in the direction in which one main surface 20A of the substrate 20 extends in FIG. 2. In this case, the infrared photodiode 1 includes plural p-electrodes 92 corresponding to the pixels while including only one n-electrode 91. Such a structure will be described in Embodiment 4 later.

In the infrared photodiode 1 according to this embodiment, in the contact layer 50, a region including the first main surface 50A, which is a main surface on the quantum well structure 40 side, has a p-type impurity concentration set to be lower than the p-type impurity concentration of a region including the second main surface 50B, which is a main surface opposite to the first main surface 50A. The region including the first main surface 50A, which is a main surface on the quantum well structure 40 side, has a p-type impurity concentration set to be lower, to thereby suppress diffusion of the p-type impurity into the quantum well structure 40, and contribute to an increase in the sensitivity. In addition, the region including the second main surface 50B, which is a main surface opposite to the first main surface 50A, has a p-type impurity concentration set to be higher, to thereby decrease the contact resistance between the contact layer 50 and the p-electrode 92 disposed so as to be in contact with the second main surface 50B. Thus, the infrared photodiode 1 according to this embodiment is a photodiode having an increased sensitivity.

Hereinafter, a method for producing the semiconductor layered structure 10 and the infrared photodiode 1 according to this embodiment will be outlined.

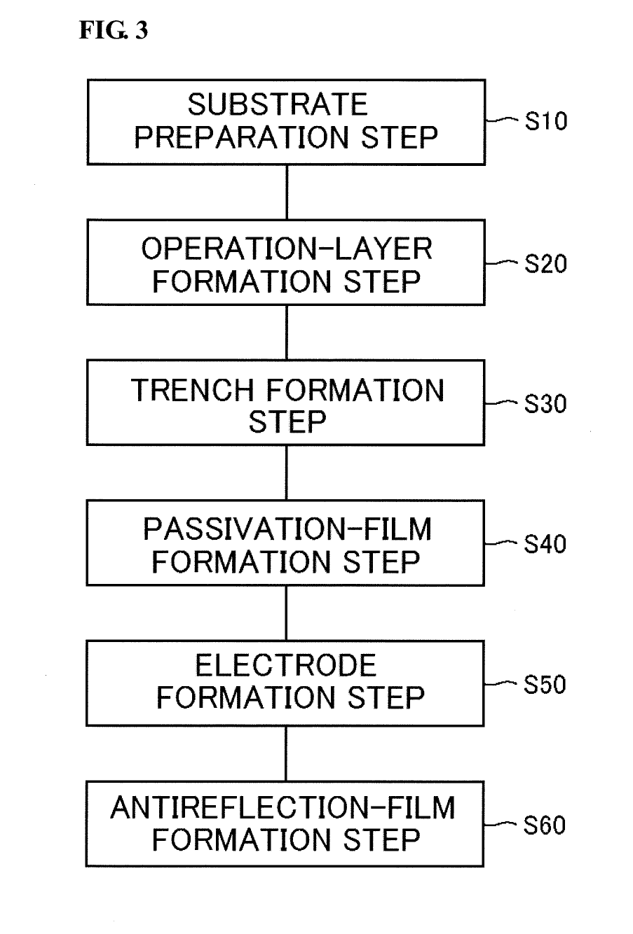

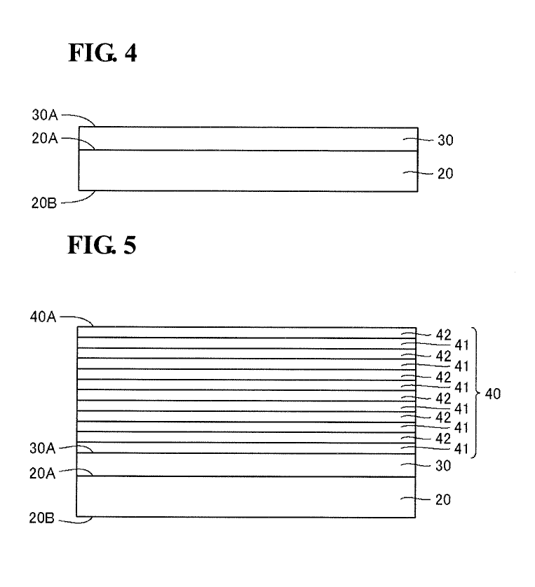

Referring to FIG. 3, in the method for producing the semiconductor layered structure 10 and the infrared photodiode 1 according to this embodiment, a substrate preparation step is first performed as Step (S10). In this Step (S10), referring to FIG. 4, for example, a substrate 20 having a diameter of 2 inches (50.8 mm) and formed of InP is prepared. More specifically, an ingot formed of InP is sliced to obtain the substrate 20 formed of InP. A surface of the substrate 20 is polished and then subjected to processes such as cleaning. Thus, the substrate 20 is prepared in which the planarity and cleanliness of one main surface 20A are ensured.

Subsequently, an operation-layer formation step is performed as Step (S20). In this Step (S20), on one main surface 20A of the substrate 20 prepared in Step (S10), a buffer layer 30, a quantum well structure 40, and a contact layer 50 are formed as operation layers. The operation layers can be formed by, for example, metal-organic vapor phase epitaxy. The formation of the operation layers by metal-organic vapor phase epitaxy can be performed by, for example, placing the substrate 20 on a rotation table equipped with a heater for heating a substrate and, under heating of the substrate 20 with the heater, supplying source gases onto the substrate.

Specifically, referring to FIG. 4, for example, an InP layer having an n-type conductivity (n-InP layer) is first formed on and in contact with one main surface 20A of the substrate 20. On the n-InP layer, an InGaAs layer having an n-type conductivity (n-InGaAs layer) is formed. The n-InP layer and the n-InGaAs layer are formed by metal-organic vapor phase epitaxy. Thus, the buffer layer 30 formed of III-V compound semiconductors and having an n-type conductivity is formed.

Subsequently, referring to FIG. 4 and FIG. 5, the quantum well structure 40 is formed on and in contact with a main surface 30A of the buffer layer 30, the main surface 30A being on a side of the buffer layer 30 opposite to the other side facing the substrate 20, by alternately stacking, for example, a first component layer 41 formed of GaAsSb as a III-V compound semiconductor, and a second component layer 42 formed of InGaAs as a III-V compound semiconductor. Following the formation of the buffer layer 30, formation of the quantum well structure 40 can be continuously performed by metal-organic vapor phase epitaxy. That is, while the substrate 20 is disposed within the apparatus having been used for forming the buffer layer 30, the source gases can be changed to thereby form the quantum well structure 40.

The first component layer 41 and the second component layer 42 may each be formed so as to have a thickness of 3 nm, for example; and, for example, 250 unit structures each constituted by the first component layer 41 and the second component layer 42 may be stacked. Thus, the quantum well structure 40 that is a type-II multiple quantum well can be formed.

Subsequently, referring to FIG. 5 and FIG. 1, a contact layer 50 formed of, for example, InGaAs (p-InGaAs) that is a III-V compound semiconductor having a p-type conductivity, is formed on and in contact with a main surface 40A of the quantum well structure 40, the main surface 40A being on a side of the quantum well structure 40 opposite to the other side facing the buffer layer 30. Following the formation of the quantum well structure 40, formation of the contact layer 50 can be continuously performed by metal-organic vapor phase epitaxy. That is, while the substrate 20 is disposed within the apparatus having been used for forming the quantum well structure 40, the source gases can be changed to thereby form the contact layer 50. Specifically, a first contact layer 51 is formed on the quantum well structure 40, and a second contact layer 52 is then formed on the first contact layer 51. In this case, the concentration of a source gas used for introducing the p-type impurity is set to be lower in the formation of the first contact layer 51 than in the formation of the second contact layer 52.

The above-described procedures complete the semiconductor layered structure 10 according to this embodiment. As described above, Step (S20) is performed by metal-organic vapor phase epitaxy, to thereby increase the production efficiency of the semiconductor layered structure 10. Incidentally, Step (S20) is not limited to a metal-organic vapor phase epitaxy that uses only metal-organic sources (metal-organic vapor phase epitaxy using only metal-organic sources), and may be performed by, for example, a metal-organic vapor phase epitaxy that uses, as the source for As, AsH₃ (arsine), which is the hydride of As. Alternatively, the semiconductor layers can be formed by a method other than metal-organic vapor phase epitaxy, for example, by MBE (Molecular Beam Epitaxy).

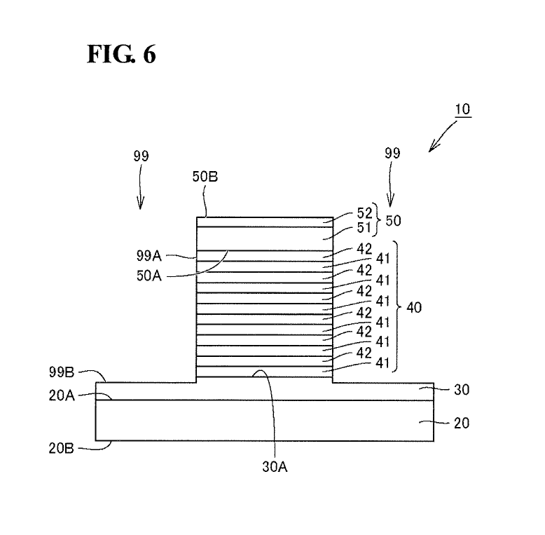

Referring to FIG. 3, subsequently, a trench formation step is performed as Step (S30). In this Step (S30), referring to FIG. 1 and FIG. 6, a trench 99 is formed in the semiconductor layered structure 10 produced in Steps (S10) and (S20) above, so as to extend through the contact layer 50 and the quantum well structure 40 to reach the buffer layer 30. The trench 99 can be formed by, for example, forming a mask layer having an opening corresponding to the shape of the trench 99, on the second main surface 50B of the contact layer 50, and subsequently performing etching.

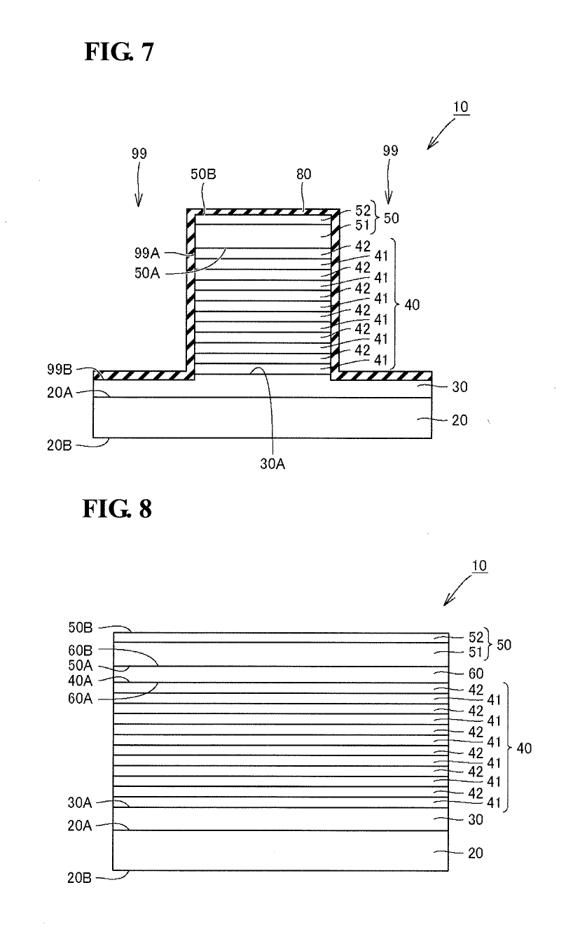

Subsequently, a passivation-film formation step is performed as Step (S40). In this Step (S40), referring to FIG. 6 and FIG. 7, a passivation film 80 is formed on the semiconductor layered structure 10 having the trench 99 formed by Step (S30). Specifically, for example, CVD (Chemical Vapor Deposition) is performed to form the passivation film 80 formed of an insulator such as silicon oxide or silicon nitride. The passivation film 80 is formed so as to cover a bottom wall 99B of the trench 99, a side wall 99A of the trench 99, and the second main surface 50B of the contact layer 50, the second main surface 50B being on a side of the contact layer 50 opposite to the other side facing the quantum well structure 40.

Subsequently, an electrode formation step is performed as Step (S50). In this Step (S50), referring to FIG. 7 and FIG. 2, an n-electrode 91 and a p-electrode 92 are formed in the semiconductor layered structure 10 having the passivation film 80 formed by Step (S40). Specifically, for example, a mask having openings at positions corresponding to regions where the n-electrode 91 and the p-electrode 92 are to be formed is formed on the passivation film 80; and openings 81 and 82 are formed in the passivation film 80 with the mask. After that, for example, vapor deposition is performed to form the n-electrode 91 and the p-electrode 92 formed of appropriate electric conductors.

Subsequently, an antireflection-film formation step is performed as Step (S60). In this Step (S60), referring to FIG. 2, an antireflection film 29 formed of, for example, SiON is formed so as to cover the other main surface 20B of the substrate 20. The antireflection film 29 can be formed by CVD, for example. The steps having been described complete the infrared photodiode 1 according to this embodiment. After that, for example, dicing is performed to provide separate devices.

### Embodiment 2

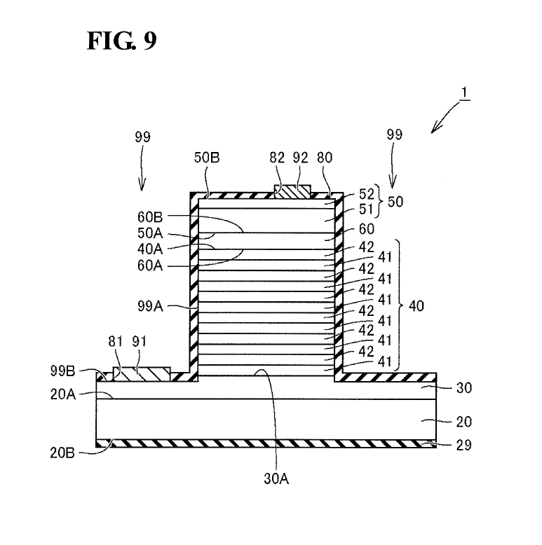

Hereinafter, Embodiment 2, which relates to a semiconductor layered structure and a photodiode according to another embodiment of the present invention, will be described. Referring to FIG. 8 and FIG. 1, a semiconductor layered structure 10 according to Embodiment 2 basically has the same structure and provides the same advantages as the semiconductor layered structure 10 according to Embodiment 1. Referring to FIG. 9 and FIG. 2, an infrared photodiode 1 according to Embodiment 2 basically has the same structure and provides the same advantages as the infrared photodiode 1 according to Embodiment 1. However, the semiconductor layered structure 10 and the infrared photodiode 1 according to Embodiment 2 are different from Embodiment 1 in that they further include a diffusion block layer 60 formed of a III-V compound semiconductor, disposed between the quantum well structure 40 and the contact layer 50, and having a p-type impurity concentration of 1×10¹⁶ cm⁻³ or less. In the semiconductor layered structure according to this embodiment, the diffusion block layer 60 having a low p-type impurity concentration is disposed between the contact layer 50 and the quantum well structure 40, to thereby suppress diffusion of the p-type impurity into the quantum well structure 40 with more certainty.

One main surface 60A of the diffusion block layer 60 is in contact with the quantum well structure 40, and the other main surface 60B is in contact with the contact layer 50. The diffusion block layer 60 is formed of a III-V compound semiconductor. The material for forming the diffusion block layer 60 can be selected in consideration of lattice-matching with the quantum well structure 40 and the contact layer 50. Specifically, the diffusion block layer 60 can be formed of, for example, InGaAs or GaAsSb. The p-type impurity contained in the diffusion block layer 60 can be at least one element selected from the group consisting of Zn, Be, Mg and C. The diffusion block layer 60, which has a lower content of such a p-type impurity preferably contained in the contact layer 50, is employed to thereby suppress diffusion of the p-type impurity into the quantum well structure. Thus, the sensitivity can be effectively increased.

The diffusion block layer 60 can have a thickness of 100 nm or more and 2000 nm or less. When the diffusion block layer 60 has a thickness of less than 100 nm, the effect of suppressing the diffusion becomes weak. On the other hand, when the diffusion block layer 60 has a thickness of more than 2000 nm, a high sensitivity is less likely to be achieved. When the diffusion block layer 60 is formed so as to have a thickness in the above-described range, a high sensitivity can be achieved with more certainty. Incidentally, the semiconductor layered structure 10 and the infrared photodiode 1 according to Embodiment 2 can be produced by the production method described in Embodiment 1 above in which, after the formation of the quantum well structure 40 and before the formation of the contact layer 50, the diffusion block layer 60 is formed on the quantum well structure 40 by metal-organic vapor phase epitaxy. That is, while the substrate 20 is disposed within the apparatus having been used for forming the quantum well structure 40, the source gases can be changed to thereby form the diffusion block layer 60.

### Embodiment 3

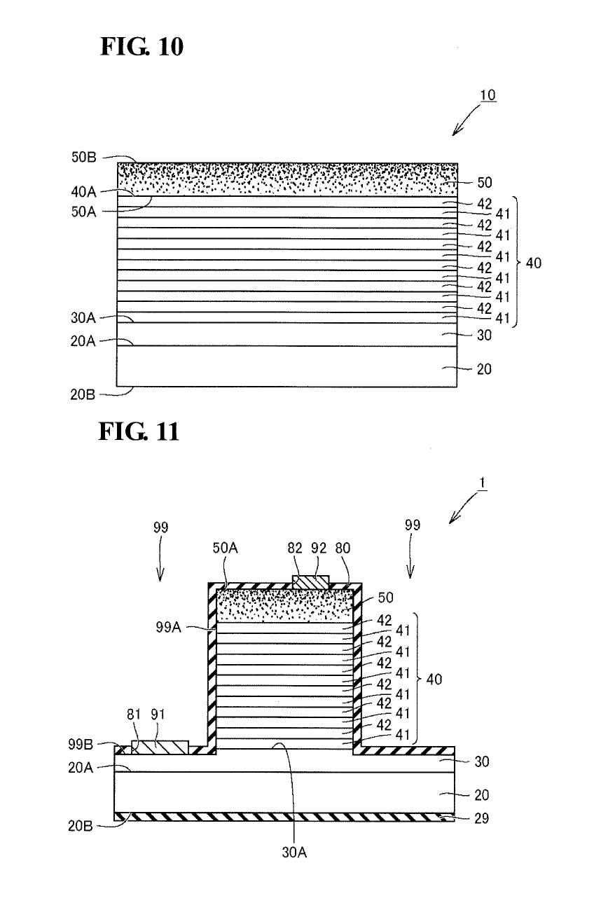

Hereinafter, Embodiment 3, which relates to a semiconductor layered structure and a photodiode according to another embodiment of the present invention, will be described. Referring to FIG. 10 and FIG. 1, a semiconductor layered structure 10 according to Embodiment 3 basically has the same structure and provides the same advantages as the semiconductor layered structure 10 according to Embodiment 1. Referring to FIG. 11 and FIG. 2, an infrared photodiode 1 according to Embodiment 3 basically has the same structure and provides the same advantages as the infrared photodiode 1 according to Embodiment 1. However, the semiconductor layered structure 10 and the infrared photodiode 1 according to Embodiment 3 are different from Embodiment 1 in terms of the structure of the contact layer 50.

In FIG. 10 and FIG. 11, dots within the contact layer 50 schematically represent the p-type impurity contained in the contact layer 50. Referring to FIG. 10 and FIG. 11, the contact layer 50 according to Embodiment 3 is constituted by a single layer that is a III-V compound semiconductor layer. In the contact layer 50, the p-type impurity concentration gradually decreases from the second main surface 50B, which is a main surface (main surface that is in contact with the p-electrode 92) opposite to the first main surface 50A, toward the first main surface 50A, which is a main surface on the quantum well structure 40 side. The p-type impurity concentration within the contact layer 50 monotonically decreases from the second main surface 50B toward the first main surface 50A. Such a structure may be employed to thereby provide the contact layer 50 in which the p-type impurity concentration of the region including the first main surface 50A is lower than that of the region including the second main surface 50B.

Incidentally, the semiconductor layered structure 10 and the infrared photodiode 1 according to Embodiment 3 can be produced by the production method described in Embodiment 1 above in which the method of forming the contact layer 50 is changed. The contact layer 50 according to Embodiment 3 can be formed by, for example, metal-organic vapor phase epitaxy. During formation of the contact layer 50, the concentration of the source gas for the p-type impurity is gradually increased, to thereby form the contact layer 50 according to Embodiment 3.

### Embodiment 4

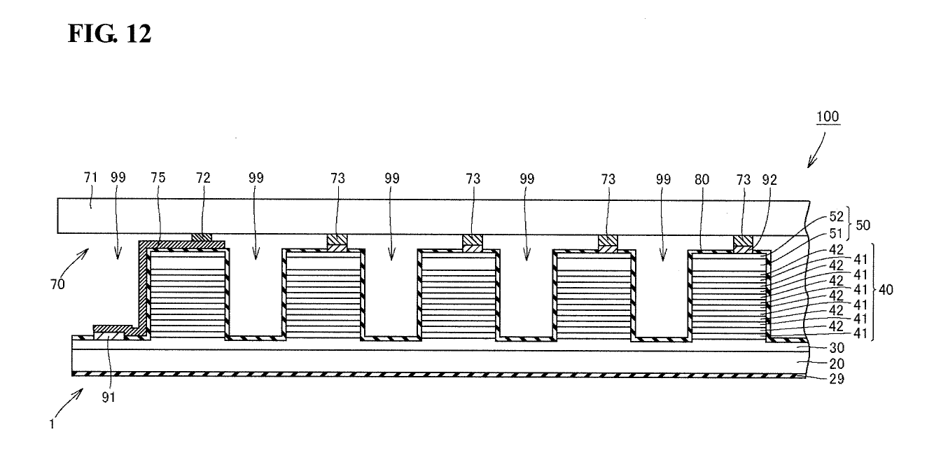

Hereinafter, a photodiode and a sensor according to Embodiment 4 of the present invention will be described. Referring to FIG. 12 and FIG. 2, an infrared photodiode 1 according to Embodiment 4 has a structure in which plural unit structures each illustrated in FIG. 2 are arranged in the direction in which one main surface 20A of the substrate 20 extends. The infrared photodiode 1 includes plural p-electrodes 92 corresponding to pixels. On the other hand, only a single n-electrode 91 is disposed.

More specifically, the n-electrode 91 of the infrared photodiode 1 according to Embodiment 4 is formed on the bottom wall of a trench 99 that is located at an end of the substrate 20 in the direction in which the substrate 20 extends. A p-electrode 92 is omitted on a contact layer 50 adjacent to the trench 99 located at the end. A sensor 100 according to this embodiment includes the infrared photodiode 1 having such a structure, and a read-out circuit (Read-Out Integrated Circuit; ROIC) 70 electrically connected to the infrared photodiode 1. The read-out circuit 70 is, for example, a CMOS (Complementary Metal Oxide Semiconductor) circuit.

Plural read-out electrodes (not shown) disposed on a body 71 of the read-out circuit 70 are electrically connected to, in one-to-one relationship, plural p-electrodes 92 functioning as pixel electrodes in the infrared photodiode 1, via bumps 73. In the infrared photodiode 1, a wiring 75 is formed that is in contact with the n-electrode 91, extends along the bottom wall and the side wall of a trench 99 having the n-electrode 91, and reaches a position over the contact layer 50. The wiring 75 is electrically connected via a bump 72 to a ground electrode (not shown) formed on the body 71 of the read-out circuit 70. Because of such a structure, absorption data of individual pixels of the infrared photodiode 1 is output from the p-electrodes 92 (pixel electrodes) to the read-out electrodes of the read-out circuit 70, and the absorption data is integrated in the read-out circuit 70, to provide, for example, a two-dimensional image.

### EXAMPLES

Samples having the same structure as the infrared photodiode 1 described in Embodiment 1 above were produced. The samples were subjected to experiments in which the sensitivity and the contact resistance between the p-electrode 92 and the contact layer 50 were measured and the properties of the devices were evaluated.

The substrate 20 was formed of InP with S (sulfur) added as an n-type impurity. The buffer layer 30 was formed so as to include an n-InP layer having a thickness of 11 nm and an overlying n-InGaAs layer having a thickness of 150 nm. The first component layer 41 and the second component layer 42 of the quantum well structure 40 were respectively a GaAsSb layer (thickness: 3 nm) and an InGaAs layer (thickness: 3 nm); and a structure in which this combination was repeated for 250 periods was employed. The first contact layer 51 was formed so as to have a thickness of 400 nm. The second contact layer 52 was formed so as to have a thickness of 100 nm. The contact layer 50 was formed as a p-InGaAs layer containing Zn as the p-type impurity. Samples (Samples 1, 2, 3, 5, and 6) were produced such that the p-type impurity concentration of the first contact layer 51 was lower than the p-type impurity concentration of the second contact layer 52. For comparison, Samples (Samples 4, 7, and 8) were also produced such that the p-type impurity concentration of the first contact layer 51 was higher than the p-type impurity concentration of the second contact layer 52. Each of Samples was measured in terms of sensitivity to light of a wavelength of 2.2 μm and contact resistance between the p-electrode 92 and the contact layer 50 under conditions of a reverse bias of −1 V and a temperature of −60° C. The results of the experiments are described in Table 1.

TABLE 1

| | Impurity concentration | | | | |
|---|---|---|---|---|---|
| | (cm⁻³) | | | | |
| | Second | First | Contact | | |
| | contact | contact | resistance | Sensitivity | |
| | layer | layer | (Ω cm²) | (A/W) | Evaluation |
| Sample 1 | 5.0 × 10¹⁸ | 4.9 × 10¹⁷ | 1.0 × 10⁻⁴ | 1.5 | A |
| Sample 2 | 5.0 × 10¹⁸ | 1.0 × 10¹⁸ | 1.0 × 10⁻⁴ | 1.0 | B |
| Sample 3 | 5.0 × 10¹⁸ | 4.9 × 10¹⁸ | 1.0 × 10⁻⁴ | 0.5 | C |
| Sample 4 | 5.0 × 10¹⁸ | 5.1 × 10¹⁸ | 1.0 × 10⁻⁴ | 0.2 | D |
| Sample 5 | 1.0 × 10¹⁸ | 9.8 × 10¹⁷ | 3.0 × 10⁻⁴ | 1.2 | B |
| Sample 6 | 8.0 × 10¹⁷ | 7.0 × 10¹⁷ | 9.0 × 10⁻⁴ | 1.2 | B |
| Sample 7 | 5.0 × 10¹⁷ | 5.1 × 10¹⁷ | 5.0 × 10⁻³ | 1.2 | D |
| Sample 8 | 4.0 × 10¹⁷ | 5.1 × 10¹⁷ | 6.0 × 10⁻³ | 1.2 | D |

Samples 1, 2, 3, 5, and 6 are Samples of Examples, whereas Samples 4, 7, and 8 are Samples of Comparative Examples. In the column of Evaluation in Table 1, a Sample particularly preferred in terms of contact resistance and sensitivity is described as A, a preferred Sample is described as B, an acceptable Sample is described as C, and an insufficient Sample is described as D.

Referring to Table 1, Samples 1, 2, 3, 5, and 6 in which the p-type impurity concentration is lower in the first contact layer 51 than in the second contact layer 52, each provide acceptable results in terms of contact resistance and sensitivity. In these Samples of Examples, the first contact layer 51 has a p-type impurity concentration of less than 5.0×10¹⁸ cm⁻³. In particular, Samples 1, 5, and 6 in which the first contact layer 51 has a p-type impurity concentration of less than 1.0×10¹⁸ cm⁻³, each provide a high sensitivity. Furthermore, Sample 1 in which the first contact layer 51 has a p-type impurity concentration of less than 5.0×10¹⁷ cm⁻³, provides a higher sensitivity. The second contact layers 52 each have a p-type impurity concentration of 8.0×10¹⁷ cm⁻³ or more. In particular, Samples 1, 2, 3, and 5 in which the second contact layer 52 has a p-type impurity concentration of 1.0×10¹⁸ cm⁻³ or more, each provide a decreased contact resistance. Furthermore, Samples 1, 2, and 3 in which the second contact layer 52 has a p-type impurity concentration of 5.0×10¹⁸ cm⁻³ or more, each provide a further decreased contact resistance. Another Sample (not described in Table 1) was produced under the same conditions as in Sample 2 so as to further include a diffusion block layer constituted by a p-InGaAs layer (thickness: 1000 nm) containing 1×10¹⁶ cm⁻³ or less of Zn as the p-type impurity, and disposed between the quantum well structure and the contact layer. This Sample was evaluated as above. This Sample was found to maintain a contact resistance similar to that of Sample 2, but found to have an increased sensitivity similar to that of Sample 1, and thus evaluated as A.

On the other hand, Samples 4, 7, and 8 in which the p-type impurity concentration is higher in the first contact layer 51 than in the second contact layer 52, each provide an insufficient result in terms of contact resistance or sensitivity.

The above-described experimental results demonstrate that photodiodes according to the present invention enable an increase in the sensitivity.

Embodiments and Examples disclosed herein are mere examples in all respects and should be understood as being non-limitative in any perspective. The scope of the present invention is defined not by the above-described description, but by Claims. The scope of the present invention is intended to embrace all the modifications within the meaning and range of equivalency of the Claims.

### INDUSTRIAL APPLICABILITY

A semiconductor layered structure, a photodiode, and a sensor according to the present application are, in particular, advantageously applicable to photodiodes and sensors demanded to have increased sensitivity and also to semiconductor layered structures used for producing such photodiodes and sensors.

### REFERENCE SIGNS LIST

1 infrared photodiode; 10 semiconductor layered structure; 20 substrate; 20A one main surface of substrate; 20B the other main surface of substrate; 29 antireflection film; 30 buffer layer; 30A main surface of buffer layer; 40 quantum well structure; 40A main surface of quantum well structure; 41 first component layer; 42 second component layer; 50 contact layer; 50A first main surface of contact layer; 50B second main surface of contact layer; 51 first contact layer; 52 second contact layer; 60 diffusion block layer; 60A one main surface of diffusion block layer; 60B the other main surface of diffusion block layer; 70 read-out circuit; 71 body; 72 and 73 bumps; 75 wiring; 80 passivation film; 81 and 82 openings; 91 n-electrode; 92 p-electrode; 99 trench; 99A side wall of trench; 99B bottom wall of trench; 100 sensor

1. A semiconductor layered structure comprising:
a base layer formed of a III-V compound semiconductor and having an n-type conductivity;
a quantum well structure formed of a III-V compound semiconductor; and
a contact layer formed of a III-V compound semiconductor and having a p-type conductivity,
wherein the base layer, the quantum well structure, and the contact layer are disposed so as to be stacked in this order, and
in the contact layer, a region including a first main surface that is a main surface on a quantum well structure side has a p-type impurity concentration lower than a p-type impurity concentration of a region including a second main surface that is a main surface opposite to the first main surface.

2. The semiconductor layered structure according to claim 1, wherein the contact layer includes
a first contact layer disposed so as to include the first main surface, and
a second contact layer disposed so as to include the second main surface, and
a p-type impurity concentration of the first contact layer is lower than a p-type impurity concentration of the second contact layer.

3. The semiconductor layered structure according to claim 2, wherein the first contact layer has a p-type impurity concentration of less than 5×10¹⁸ cm⁻³.

4. The semiconductor layered structure according to claim 2, wherein the second contact layer has a p-type impurity concentration of 8×10¹⁷ cm⁻³ or more.

5. The semiconductor layered structure according to claim 1, further comprising a diffusion block layer formed of a III-V compound semiconductor, disposed between the quantum well structure and the contact layer, and having a p-type impurity concentration of 1×10¹⁶ cm⁻³ or less.

6. The semiconductor layered structure according to claim 5, wherein the diffusion block layer contains a p-type impurity that is at least one element selected from the group consisting of Zn, Be, Mg, and C.

7. The semiconductor layered structure according to claim 5, wherein the diffusion block layer has a thickness of 100 nm or more and 2000 nm or less.

8. The semiconductor layered structure according to claim 1, wherein the quantum well structure is a type-II structure including a repeating structure selected from the group consisting of InGaAs/GaAsSb, GaInNAs/GaAsSb, and InAs/GaSb.

9. A photodiode comprising:
the semiconductor layered structure according to claim 1; and
an electrode formed on the semiconductor layered structure.

10. A sensor comprising:
the photodiode according to claim 9; and
a read-out circuit connected to the photodiode.
